(19) United States
(12) Patent Application Publication
(10) Pub. No.: US 2006/0115591 A1
(43) Pub. Date: Jun. 1, 2006

(54) Pentaborane(9) storage and delivery

(76) Inventors: W. Karl Olander, Indian Shores, FL (US); Jose I. Arno, Brookfield, CT (US)

Correspondence Address: ATMI, INC., 7 COMMERCE DRIVE, DANBURY, CT, 06810, US

(21) Appl. No.: 10/998,680

(22) Filed: Nov. 29, 2004

(51) Int. Cl. C23C 16/00; B67D 5/00

(52) U.S. Cl. 427/248.1; 118/715; 222/3

(57) ABSTRACT

A fluid storage and dispensing system comprising a vessel for holding a pentaborane(9)-containing fluid at subatmospheric pressure. The fluid storage and dispensing system may be communicatively connected to a semiconductor or liquid crystal display manufacturing facility, whereby the pentaborane(9) is used as a substitute for commercially available boron hydride compounds such as diborane.

### FIELD OF THE INVENTION

The present invention relates generally to the storage and delivery of pentaborane(9) (B₅H₉) and other higher-order boron hydrides for use as a source of boron for semiconductor integrated circuit manufacture.

### DESCRIPTION OF THE RELATED ART

Diborane (B₂H₆) is used extensively as the boron precursor in chemical vapor deposition (CVD) and other doping applications. However, a disadvantage of diborane is its high reactivity and thermal instability. To suppress its reactivity, diborane is typically shipped as a dilute mixture, e.g., 5%, in hydrogen. Unfortunately, the diborane in the dilute shipping mixture continuously decomposes over time to form higher molecular weight species and/or particulate matter and as such, the concentration of diborane is continuously decreasing as the dilute diborane mixture ages (see, e.g., Flaherty, E. T., Marshall, J., Albert, P., Brzychcy, A. M., Forbes, D., J. Electrochem. Soc., 140(6), 1709-13 (1993)). Disadvantages of using dilute diborane include frequent cylinder changes, costly requalification runs and material which is no longer consistent with the product specification. In addition, because of continuous concentration changes, a gas stream delivering diborane to a semiconductor tool must be monitored continuously and modulated accordingly to ensure delivery of a constant concentration of diborane to said tool.

Alternatively, the use of higher-order boron hydride clusters has been proposed for use in the semiconductor industry, however, higher-order boron hydride clusters are either unstable or solids with low vapor pressures, e.g., decaborane. To overcome the low vapor pressures, the user must heat the solid-source and heat trace the delivery lines resulting in complex, cumbersome and expensive systems.

Recently, pentaborane(9) (B₅H₉) has become an attractive alternative to diborane. Although not wishing to be bound by theory, deposition or doping processes using diborane as a precursor may include the formation of pentaborane(9) species and thus, it is proposed that it may be more efficient to start with pentaborane(9) compounds. However, pentaborane(9), a higher-order boron hydride, is about 10 times more toxic than diborane, by volume. In addition, B₅H₉ has been used as a fuel additive in rockets, missiles and military jet aircraft because of its high energy releases when burned with fuels in air. As such, to date few in the semiconductor industry have expressed any interest in making or using pentaborane(9).

Pentaborane(9) is a low vapor pressure colorless liquid with a pungent odor that is detectable at concentrations as low as 0.8 ppm. The threshold limit value (TLV) of B₅H₉ is 0.005 ppm and exposure to low concentrations of B₅H₉ may result in dizziness, blurred vision, nausea, fatigue, light headedness or nervousness. In addition, abnormal muscular contractions, breathing difficulty, poor muscular coordination, convulsions and coma have been reported to be the result of B₅H₉ exposure.

Pentaborane(9) is the most stable of the higher-order boron hydrides. It has been reported that pure B₅H₉ is thermally stable and only begins to decompose at temperatures in excess of 150° C., forming decaborane, hydrogen and non-volatile solid boron hydrides, with a concomitant buildup of pressure in the vessel. Pentaborane(9) is insensitive to shock (but can form shock sensitive mixtures with chlorinated organic compounds) and is soluble, without reaction, in hydrocarbons such as benzene, toluene, hexane, kerosene and mineral oil. In addition, B₅H₉ is compatible with most common materials of packaging construction including; anodized aluminum, bronze, copper, magnesium alloys, nickel, low carbon steel, titanium alloys, aluminum alloys, brass, carbon, lead, monel, cadmium plated steel, stainless steel, graphite packing, glass, Viton®, Glyptal sealant, asbestos, KEL-F®, Teflon® and Hycar® rubber.

It has been widely recognized that B₅H₉ must be handled with extreme caution because of its extremely toxic and pyrophoric nature and as such, requires special packaging, sensing and abatement considerations. Pentaborane(9) is therefore oftentimes stored in cylinders or containers that secure the material and prevent its introduction to air. In the past, B₅H₉ cylinders were of significant size and stored in relatively cool environments such as underground facilities or bunkers. Of even greater concern is the transport of a cylinder containing B₅H₉ from the distributor to the purchaser. Such transportation involves inherent risks to the general public as well as those directly involved in transporting the cylinder. The movement of such a hazardous material understandably involves and concerns a variety of state and federal environmental regulatory persons, depending on the particular circumstances. Even if the pentaborane(9) container is in good condition, the catastrophic consequences of an in-transit accident render shipment of the cylinder difficult, costly and effectively unfeasible.

Importantly, it is necessary to maintain complete structural integrity in the storage, transport and deployment of such vessels, so that no leakage of contained fluid takes place, such as by leakage through couplings, valve head fittings, burst disks or other pressure relief devices associated with the vessel, searns, ports or other joints where welds or bonding media may fail and result in gas release from the vessel, etc. The foregoing considerations are particularly acute where the contained fluid is very expensive and/or where chemical reagents must be >99.999% pure in order to achieve reliable and acceptable integrated circuits. The foregoing also applies where the contained fluid is toxic or hazardous in character, and leakage may compromise human health and safety, or otherwise produce injury or adverse impact on the environment, or to the process facility in which the fluid is to be utilized.

In the field of semiconductor manufacturing, new packaging approaches have been developed in recent years, including the introduction of pressure-regulated fluid storage and dispensing vessels of the type described in Wang et al. U.S. Pat. No. 6,101,816, Wang et al. U.S. Pat. No. 6,089,027 and Wang et al. U.S. Pat. No. 6,343,476, as commercially available from ATMI, Inc. (Danbury, Conn.) under the trademark “VAC.” VAC® sources utilize internally mounted set pressure regulators to control cylinder output pressure to sub-atmospheric levels, thereby virtually eliminating the possibility of a hazardous or toxic gas leak.

It would therefore be a significant advance in the art of pentaborane(9) storage and dispensing to provide an improved storage apparatus and dispensing method based on the storage and dispensing vessel of Wang et al., which can store substantial quantities of pentaborane(9) at sub-atmospheric pressures and can safely and easily be used in the production of semiconductor and flat panel products without risk to the user.

### SUMMARY OF THE INVENTION

The present invention relates generally to the storage and delivery of pentaborane(9) (B₅H₉) and other higher-order boron hydrides for use as a source of boron for semiconductor integrated circuit manufacture. Specifically, the present invention relates generally to the safe storage and dispensing of pentaborane(9) from vessels for use as precursor and/or doping materials for the manufacture of semiconductor devices such as flat panel displays.

In one aspect, the present invention relates to a method of depositing boron on or in a substrate from a source material, comprising using as said source material a boron-containing material comprising pentaborane(9).

In yet another aspect, the present invention relates to a storage and dispensing apparatus, comprising a vessel holding pentaborane(9)-containing fluid at subatmospheric pressure, and dispensing means arranged to discharge pentaborane(9) gas from said vessel.

Other aspects, features and embodiments of the invention will be more fully apparent from the ensuing disclosure and appended claims

### BRIEF DESCRIPTION OF THE DRAWINGS

FIG. 1 is a general cross-sectional representation of the Wang et al. fluid storage and dispensing system.

FIG. 2 is a schematic representation of a fluid transfill manifold, wherein a fluid is transferred from a bulk storage tank to a fluid storage and dispensing vessel, according to one embodiment of the present invention.

FIG. 3 is an illustration of the sensitivity of a diborane specific tape as a function of pentaborane(9) concentration.

### DETAILED DESCRIPTION OF THE INVENTION AND PREFERRED EMBODIMENTS THEREOF

The present invention relates generally to the storage and delivery of pentaborane(9) (B₅H₉) and other higher-order boron hydrides for use as a source of boron for semiconductor integrated circuit manufacture. Specifically, this invention relates to a fluid storage and gas dispensing system which may be utilized to store pentaborane(9) at sub-atmospheric pressures, for dispensing of gas from the system and use of the dispensed gas in an application such as the manufacture of flat panel displays and other semiconductor devices.

The disclosures of the following U.S. patents and patent applications are hereby incorporated herein by reference in their respective entireties: U.S. Pat. No. 5,518,528 issued May 21, 1996 in the name of Glenn M. Tom and James V. McManus; U.S. Pat. No. 6,101,816 issued Aug. 15, 2000 in the name of Luping Wang and Glenn M. Tom; U.S. Pat. No. 6,089,027 issued Jul. 18, 2000 in the name of Luping Wang and Glenn M. Tom; and U.S. Pat. No. 6,343,476 issued Feb. 5, 2002 in the name of Luping Wang and Glenn M. Tom.

The main fluid supply vessel in the practice of the present invention may be of any suitable type including low pressure adsorbent-based fluid storage and dispensing vessels of the type disclosed in Tom et al. U.S. Pat. No. 5,518,528, as commercially available from ATMI, Inc. (Danbury, Conn.) under the trademark “SDS,” and pressure-regulated fluid storage and dispensing vessels having a regulator associated with the outlet port of the vessel or otherwise interiorly disposed in the interior volume of the vessel, such as those commercially available from Advanced Technology Materials, Inc. (Danbury, Conn.) under the trademarks “VAC” and “VAC-SORB.”

In a preferred embodiment of the present invention, the main fluid supply vessel is an internal regulator-equipped VAC® vessel maintained at sub-atmospheric pressures. The regulator is set at an appropriate pressure level for flow of dispensed fluid to the semiconductor manufacturing device, and the set point of the regulator for such purpose can be fixed, or the regulator may be of a variable set point character. Alternatively, the main fluid supply vessel of the present invention is an SDS® vessel containing sorbent material having macroreticular pores to ensure the B₅H₉ is desorbed from the sorbent material. “Macroreticular pores” is defined herein as corresponding to an average pore diameter ranging from 50 to 1,000,000 Å.

The fluid medium in the VAC® vessel may be any suitable fluid medium at any appropriate fluid storage conditions, e.g., a high pressure gas or alternatively a liquid, at the set point pressure determined by the fluid pressure regulator. Thus, the gas source in the system may be a high pressure gas or a liquid. Preferably, B₅H₉ is stored as a liquid in the VAC® vessel, which is contrary to conventional wisdom in the art because the dangers associated with gaseous B₅H₉ leaks are lower relative to the dangers associated with liquid B₅H₉ spills.

Optionally and desirably, a phase separator is utilized to prevent liquid leakage across the regulator valve seat when the gas source is a high pressure liquid. The phase separator may be of any suitable form, but preferably comprises a porous membrane that is permeable to gas or vapor of the contained liquid, but is impermeable to the liquid phase. Suitable materials for such phase separator permeable membrane include various polymeric material films of appropriate porosity and permeability characteristics, and so-called “breathable” fabrics such as those commercially manufactured by W. L. Gore & Associates, Inc. (Elkton, Md.) under the trademarks “Gore-Tex,” “Activent,” “DryLoft,” and “Gore Windstopper.”

The pressure regulator and the phase separator may be utilized in combination with one another in an assembly which may be positioned at or within the VAC® vessel or disposed exteriorly thereof. Preferably, such fluid pressure regulator and phase separator assembly is interiorly disposed in the VAC® vessel.

The VAC® vessel affords a high level of safety in the deployment of fluids, in that the VAC® vessel may be fabricated with an interiorly disposed pressure regulator and optional phase separator, and the seam associated with the fluid flow port of the vessel will constitute the only leak path in the otherwise seamless vessel construction. Further, in the case of a conventional fluid cylinder, because of the relative small size of the cylinder neck in contrast to the cross section of the body of the vessel, a minimal leak path for ingress or egress of gas is provided, which can be easily rendered leak-tight by brazing, welding, adhesively sealing with a highly fluid impermeable sealant, etc. As such, storage of pentaborane(9) in the VAC® vessel reduces the risk of exposure to personnel in the event of accidental opening of the cylinder, and prevents air from entering the vessel to pyrophorically react with the B₅H₉ therein.

Further advantages of the VAC® vessel for storage of pentaborane(9) include the prevention of material condensation in the lines and the prevention of back-diffusion of oxidizing or incompatible materials into vessels containing pentaborane(9).

Although the invention described herein repeatedly refers to pentaborane(9) as the material of choice, it is to be understood that homologs of pentaborane are also contemplated herein including, but not limited to, tetraborane(10) (B₄H₁₀) and pentaborane(11) (B₅H₁₁).

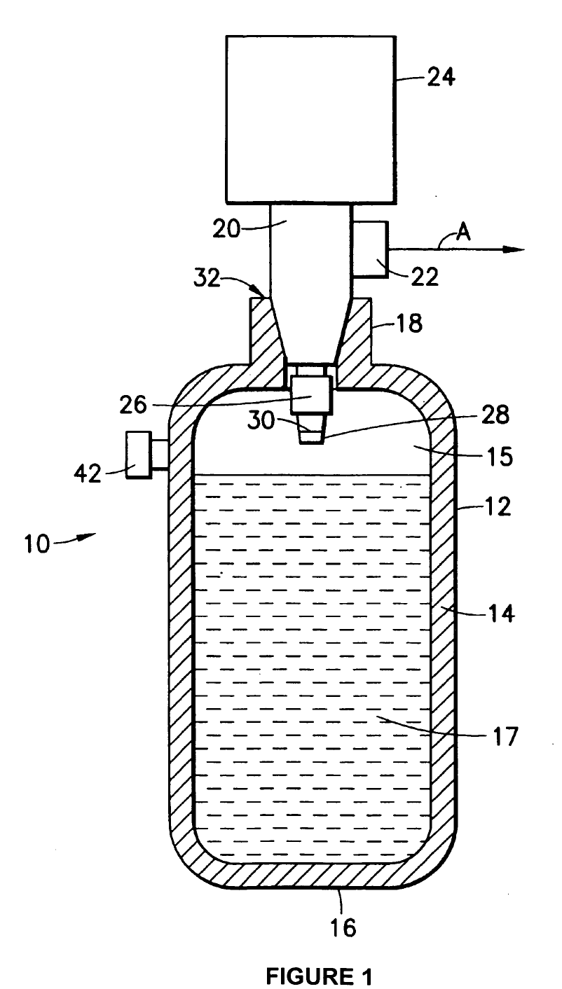

Referring to FIG. 1, the VAC® system 10 includes a storage and dispensing vessel 12 including a cylindrical side wall 14, a bottom floor 16 and an upper neck portion 18, defining an enclosed interior volume 15 holding the liquid 17. Liquid 17 may comprise any suitable boron hydride liquid such as pentaborane(9) for use in semiconductor manufacturing operations. Disposed in the upper neck portion 18 of the vessel 12 is a valve head assembly comprising valve 20 communicating with valve outlet 22, from which vapor is dispensed from the vessel in the direction indicated by arrow A.

The valve 20 is shown with an associated actuator 24, which may be of any suitable type (electrical, pneumatic, etc.) as desired in the given end use application of the invention. Alternatively, the valve 20 may be manually actuated, or provided with other flow control means. The valve 20 is joined in gas flow communication with the pressure regulator 26, which may be of a conventional type employing a poppet element which may for example be spring biased in a closed condition, and wherein the poppet is subject to displacement when the pressure differential across the poppet element exceeds a certain level. The pressure regulator 26 may for example be set to a subatmospheric, atmospheric or superatmospheric pressure value, e.g., 700 Torr. The specific pressure level is chosen with respect to the liquid or other fluid contained in the vessel, as appropriate to the storage and dispensing operation.

Coupled with the pressure regulator 26 is a phase separator 28, including a membrane element 30, which is permeable to gas or vapor deriving from the liquid 17, but is impermeable to the liquid itself.

Prior to filling, the storage and dispensing vessel 12 should be completely free of all oxides and other foreign matter which is not compatible with B₅H₉, dried to a −20° C. dew point, and inerted completely with a dry gas such as nitrogen. Any moisture present will induce slow hydrolysis of B₅H₉ and result in undesirable products in the liquid as well as a buildup of pressure in the cylinder due to hydrogen evolution. Pentaborane(9) may be stored at ambient temperatures for several years without change in its purity if the vessel is clean prior to filling and a dry inert atmosphere is maintained above the liquid. The long-term stability of pentaborane under controlled conditions is a significant improvement over more unstable boron hydrides such as diborane.

The pressure at which neat B₅H₉ may be stored in the vessels described herein includes subatmospheric, atmospheric or superatmospheric, most preferably subatmospheric. For example, 100 g of B₅H₉ may be stored in a 2.2 L VAC® vessel at 500 Torr. “Neat” is defined herein as a substance substantially free of admixture or dilution, preferably at least 90% pure, more preferably at least 95% pure, and most preferably at least 99% pure. Alternatively, the B₅H₉ may be dissolved in a high molecular weight, low vapor pressure solvent in the VAC® vessel. The solvent must be inert and must have a negligible vapor pressure. It is thought that the solvent reduces the reactivity, i.e., flammability, of the B₅H₉, which then may be handled in air without incident. Although not wishing to be bound by theory, it is assumed that the solvent in the admixture makes the B₅H₉ less accessible to air, lowering the vapor pressure of the B₅H₉ and concomitantly the risk of reaction with air. Solvents contemplated herein include, but are not limited to, straight-chained or branched C₁₂-C₂₀ alkanes optionally substituted with alkyl groups, mineral oil and linear or branched paraffins having the formula CₙH₂ₙ₊₂ where n is greater than 20. Preferably, the solvent includes mineral oil. The B₅H₉ concentration in solvent may be in a range from about 10% by weight to about 90% by weight, preferably about 30% by weight to about 70% by weight, most preferably about 50% by weight, based on the total weight of the solution.

Sources of pentaborane(9) include, but are not limited to, formation by the pyrolysis of diborane in hydrogen at 250° C. or formation using boric acid as the initial boron precursor as described in Adams et al. (Adams, L., Hosmane, S. N., Eklund, J. E., Spielvogel, B. F., Hosmane, N. S., J. Am. Chem. Soc., 124, 7292-7293 (2002)). It is understood by one skilled in the art that great care must be exercised when synthesizing pentaborane(9) due to the toxicity and pyrophoricity of said compound.

In use of the liquid storage and gas dispensing system of FIG. 1, the liquid is stored at a predetermined pressure ensuring its liquidity. For this purpose, the pressure regulator 26 is set at a predetermined level ensuring the appropriate interior pressure in the interior volume 15 of the vessel. The liquid-impermeable, gas/vapor-permeable membrane 30 ensures that no liquid will flow into the gas regulator 26, even if the vessel is tilted from the vertical attitude shown in FIG. 1.

When it is desired to dispense gas from the vessel 12 to the semiconductor manufacturing facility, the valve actuator 24 is actuated to open valve 20, thereby permitting gas or vapor deriving from the liquid to flow through the permeable membrane 30, the pressure regulator 26 and the valve 20, for egress from the valve head dispensing assembly through outlet 22. The opening of the valve 20 effects a reduction of the pressure on the discharge side of the permeable membrane 30 and causes permeation of vapor deriving from the liquid through the membrane, for discharge. At the same time, the fluid pressure regulator will maintain the pressure of the gas being dispensed at the set point pressure level.

If the semiconductor manufacturing process requires a pressure of B₅H₉-containing gas greater than 200 Torr, i.e., the vapor pressure of B₅H₉, a mechanical pump or venturi may be positioned at a location upstream of the VAC® vessel to extract the B₅H₉-containing gas from the vessel. Arrangement of the necessary valving and the pump or venturi relative to the VAC® vessel is well within the knowledge of a person skilled in the art.

The valve actuator 24 may be controlled by a central processor unit, which may comprise a computer or microprocessor control apparatus, coupled in controlling relationship with the valve actuator 24 by means of signal transmission line (not shown).

The semiconductor manufacturing facility may comprise any suitable arrangement of semiconductor process equipment for the production of semiconductor materials or devices or liquid crystal display (LCD) devices, or products containing such materials or devices. For example, the semiconductor manufacturing facility may comprise an ion implantation system, chemical vapor deposition reactor and associated reagent supply and vaporization equipment (including liquid delivery equipment, bubblers, etc.), etch unit, cleaning apparatus, etc. Preferably, the semiconductor manufacturing facility is a boron cluster ion implantation system or a plasma-assisted CVD. More preferably, the facility manufactures LCD flat panels.

Alternatively, to dispense gas from the vessel 12 a delivery gas, such as helium or nitrogen, may be bubbled through a bubbler assembly along with the liquid pentaborane(9) at the appropriate temperature and pressure to obtain the desired gas flow rates for introduction into the semiconductor manufacturing facility. This permits the adjustment of the pentaborane(9) concentration, for example 100 ppm B₅H₉ in the gas stream to be introduced into the semiconductor fab.

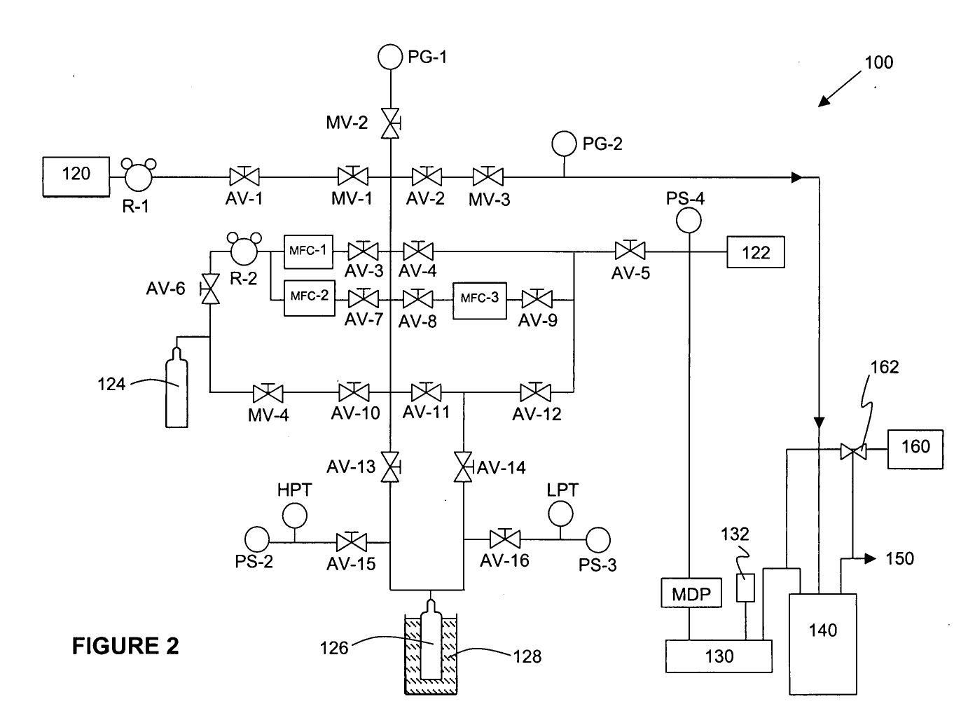

The VAC® vessel may be transfilled according to the following embodiment. As defined herein, “transfilling” is the process of transferring a material from one vessel to another, for example from a large volume high pressure cylinder or liquid source vessel 124 to a smaller volume VAC® vessel 126. For ease of reference in the ensuing discussion, a generalized description of a transfilling manifold 100 is set out below with respect to FIG. 2, which schematically represents a VAC® vessel 126 installed and positioned within a liquid nitrogen bath 128 to effectuate a cryogenic transfill. By placing the vessel in a cryostat or coolant bath, the temperature of the vessel is reduced to a value below the point of the predetermined pressure established by the pressure regulator. The fluid pressure regulator then will have a gas pressure in the interior volume 15 of the vessel which is below the set point of the regulator, thereby allowing the poppet element of the pressure regulator to disengage from its seat and allow ingress of fluid to the vessel, for subsequent storage of the liquid therein. Importantly, B₅H₉ will be in the gaseous phase during transfer from the vessel 124 to a smaller volume VAC® vessel 126. This is preferred because the dangers associated with gaseous B₅H₉ leaks are lower relative to the dangers associated with liquid B₅H₉ spills.

It is also contemplated herein that vessel 124 is not a vessel at all but rather a site where pentaborane(9) is synthesized for passage to the VAC® vessel. Alternatively, reference number 124 may be a holding chamber positioned downstream from a pentaborane(9) synthesis wherein the pentaborane(9) is stored in the holding chamber until a pre-determined pressure threshold is reached. This serves to allow immediate gas flow to the VAC® vessel 126 on demand to shorten the “waiting-period” associated with synthesis.

The transfilling manifold is cycle purged (described below) and under vacuum conditions with all of the valves closed. To transfill, the cylinder valve of the pentaborane(9) liquid source 124 is opened. Then, automatic valves (AV) AV-10 and AV-13 and the VAC® vessel 126 fill port valve are opened. To begin the transfer of pentaborane(9) from the liquid source 124 to the VAC® vessel 126, manual valve (MV) MV-4 is opened. Following approximately 3-4 hours of transfer, the cylinder valve of the liquid source 124 and the fill port valve of the VAC® vessel 126 are closed. Importantly, during pentaborane(9) transfer, the user must ensure that the liquid nitrogen bath 128 remains filled. Following cycle purging of the transfilling manifold 100, the VAC® vessel 126 and the liquid source 124 are removed and weighed to determine the mass of pentaborane(9) transferred.

Cycle purging of the transfilling manifold 100 may be effected as follows. The VAC® vessel 126 and the liquid source 124 are installed, the manifold evacuated to vacuum conditions and all of the valves closed. The nitrogen gas regulator R-1 is set to a pressure of 30 psig and the nitrogen vessel valve 120 is opened. AV-1, AV-11, AV-13, AV-14 and AV-15 are opened. Then, MV-1 is opened to charge the manifold with 30 psig of N₂. Following approximately 5 seconds, AV-1 is closed. Then, AV-12 and AV-5 are opened to vent the purge N₂ through the pump. Following approximately 10 seconds, AV-12 and AV-5 are closed. AV-1 is re-opened to recharge the system with 30 psig of N₂. Following 5 seconds, AV-1 is closed and the purging and recharging subsequently repeated for about 10 to about 25 times, preferably 20 times. Importantly, if the appropriate vacuum level is not achieved during the initial evacuation of the manifold, a leak is present in the manifold.

In one embodiment, pentaborane(9) detectors are present during pentaborane(9) transfilling or dispensing to ensure B₅H₉ has not leaked during the respective processes. Preferable methods of sensing pentaborane(9) include, but are not limited to, calibration using tape-based sensors, qualitative measurements using Kitagawa-type sensor tubes and quantitative measurements using Fourier Transform Infrared spectroscopy (FTIR). For example, the pentaborane(9) detectors may be positioned in the manifold environment to sense manifold leaks and/or at locations in the manifold flow lines to detect B₅H₉ concentration levels. An example of the latter includes a detector positioned to sense pentaborane(9) exiting a pumping means 130 or a scrubbing means 140 and may include a three-way valve 162 to sample the concentration of B₅H₉ in the pump exhaust or the scrubber exhaust.

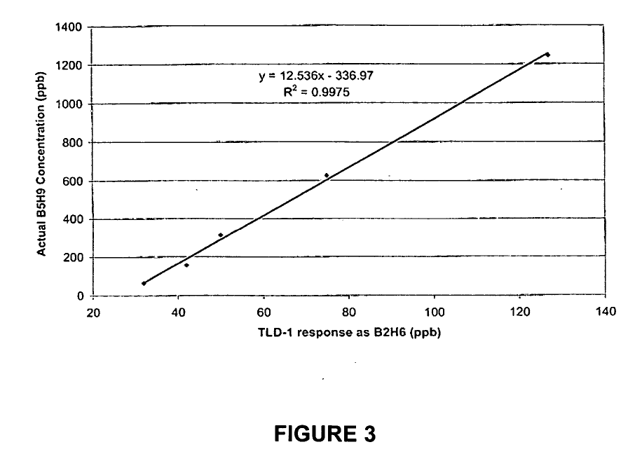

Tape-based sensors include, but are not limited to, the MDA Scientific TLD monitors (Zellweger Analytics, Lincolnshire, Ill.), wherein an air sample is exposed to a chemically treated tape. The gas specific tape changes color if the gas is detected, said color change correlating to a gas concentration. In the present case, tape specific to diborane may be used, the sensor response being readily correlated to pentaborane(9) concentration levels (see, e.g., FIG. 3, which illustrates the sensitivity of the diborane specific tape as a function of pentaborane(9) concentration).

FTIR analysis of B₅H₉ may be performed using a 10 m long-pathlength MIDAC I-2000 FTIR spectrometer and the spectral profile compared to published pentaborane(9) spectrums (see, e.g., Hrostowski, H. J., et al., J. Am. Chem. Soc., 76, 998 (1953)).

Another aspect of the invention relates to a fluid storage and dispensing system comprising a vessel containing a heat sink material, such as ball bearings, which absorb heat if any air ingresses into the VAC® vessel. Other heat sink materials contemplated include, but are not limited to, porous particulate material, monolithic materials, and metal bearings having generally spherical and/or polygonal shapes.

The liquid source vessel, VAC® vessel and manifold in the practice of the invention may be disposed in a gas cabinet, or alternatively may be provided as a unitary assembly in an “open air” manifold system, wherein the gas manifold is mounted on a unistrut wall, rack, gas panel board, or other support structure, and the gas source vessel is coupled to same.

It is to be appreciated by one skilled in the art that the transfilling manifold described herein represents one embodiment thereof. The components of the manifold may be arranged differently, as readily determined by one skilled in the art, with the purpose of transfilling using said rearranged manifold. It is noted that a series of valves and other controllers may be positioned at locations on the manifold, for example, pressure regulating valves, check valves, shut-off valves, isolation valves, over-pressure relief valves, mass-flow control valves, etc., as readily determined by one skilled in the art.

While the invention has been described herein with reference to various specific embodiments, it will be appreciated that the invention is not thus limited, and extends to and encompasses various other modifications and embodiments, as will be appreciated by those ordinarily skilled in the art. Accordingly, the invention is intended to be broadly construed and interpreted, in accordance with the ensuing claims.

What is claimed is:

1. A method of depositing boron on or in a substrate from a source material, comprising using as said source material a boron-containing material comprising pentaborane(9).

2. The method of claim 1, wherein boron is deposited on or in the substrate by ion implantation.

3. The method of claim 2, wherein the deposited boron comprises ionic boron.

4. The method of claim 1, wherein the source material comprises neat pentaborane(9).

5. The method of claim 1, wherein the source material comprises a solvent selected from the group consisting of straight-chained and branched C₂-C₂₀ alkanes, mineral oil, and linear and branched paraffins having the formula CₙH₂ₙ₊₂, where n is greater than 20.

6. The method of claim 1, wherein the source material comprises mineral oil.

7. The method of claim 1, further comprising supplying the source material from a fluid storage and dispensing apparatus, said fluid storage and dispensing apparatus comprising:
(a) a fluid storage and dispensing vessel enclosing an interior volume for holding the source material, wherein the vessel includes a fluid flow port;
(b) a fluid dispensing assembly coupled in fluid flow communication with the port;
(c) a fluid pressure regulator interiorly disposed in the interior volume of the vessel, and arranged to maintain a predetermined pressure in the interior volume of the vessel; and
(d) the fluid dispensing assembly being selectively actuatable to flow pentaborane(9) gas, deriving from the source material in the interior volume of the vessel, through the fluid pressure regulator and fluid dispensing assembly, for discharge of the pentaborane(9) gas from the vessel.

8. The method of claim 7, wherein said supplying comprises involving a exterior dispensing pressure that is lower than a storage pressure of said source material in said fluid storage and dispensing apparatus.

9. The method of claim 1, wherein the source material is supplied from a fluid source selected from the group consisting of bubblers, sorbent-based storage and dispensing systems, and internally pressure-regulated source material storage and dispensing systems.

10. The method of claim 7, wherein the pressure of source material in the fluid storage and dispensing vessel is subatmospheric.

11. The method of claim 7, wherein presence of source material exterior of said storage and dispensing vessel is detected using a sensing means selected from the group consisting of tape-based sensors, sensor tubes and Fourier Transform Infrared spectroscopy.

12. A storage and dispensing apparatus, comprising a vessel holding pentaborane(9)-containing fluid at subatmospheric pressure, and dispensing means arranged to discharge pentaborane(9) gas from said vessel.

13. The apparatus of claim 12, wherein the vessel comprises:
(a) an interior volume for holding the pentaborane(9)-containing fluid, wherein the vessel includes a fluid flow port;
(b) a fluid dispensing assembly coupled in fluid flow communication with the port;
(c) a fluid pressure regulator interiorly disposed in the interior volume of the vessel, and arranged to maintain a predetermined pressure in the interior volume of the vessel; and
(d) the fluid dispensing assembly being selectively actuatable to flow pentaborane(9) gas, deriving from the pentaborane(9)-containing fluid in the interior volume of the vessel, through the fluid pressure regulator and fluid dispensing assembly, for discharge of the pentaborane(9) gas from the vessel.

14. The apparatus of claim 13, wherein said discharging comprises involving a exterior dispensing pressure that is lower than a storage pressure of said pentaborane(9)-containing fluid in said vessel.

15. The apparatus of claim 12, wherein the pentaborane(9)-containing fluid is discharged from a fluid source selected from the group consisting of bubblers, sorbent-based storage and dispensing systems, and internally pressure-regulated source material storage and dispensing systems.

16. The apparatus of claim 12, wherein the pentaborane(9)-containing fluid comprises a hydrocarbon solvent selected from the group consisting of straight-chained and branched C₁₂-C₂₀ alkanes, mineral oil, and linear and branched paraffins having the formula CₙH₂ₙ₊₂, where n is greater than 20.

17. The apparatus of claim 12, wherein the pentaborane(9)-containing fluid comprises mineral oil.

18. The apparatus of claim 12, wherein the pentaborane(9)-containing fluid comprises neat pentaborane(9).

19. The apparatus of claim 12, further comprising sensing means to detect presence of pentaborane(9)-containing fluid exterior of said storage and dispensing vessel, wherein said sensing means is selected from the group consisting of tape-based sensors, sensor tubes and Fourier Transform Infrared spectroscopy.
